(19) United States
(12) Patent Application Publication
(10) Pub. No.: US 2025/0379126 A1
(43) Pub. Date: Dec. 11, 2025

(54) SEMICONDUCTOR DEVICE AND METHOD OF MANUFACTURING SEMICONDUCTOR DEVICE

(71) Applicant: ROHM CO., LTD., Kyoto (JP)

(72) Inventor: Taro HAYASHI, Kyoto (JP)

(21) Appl. No.: 19/221,620

(22) Filed: May 29, 2025

(30) Foreign Application Priority Data
Jun. 5, 2024 (JP) 2024-091330

(51) Int. Cl. H01L 23/495; H01L 21/48; H01L 21/56; H01L 23/00; H01L 23/31

(52) U.S. Cl. CPC H01L 23/49548; H01L 21/4825; H01L 21/4828; H01L 21/4842; H01L 23/3107; H01L 23/49582; H01L 24/16; H01L 21/56; H01L 24/11; H01L 24/81; H01L 2224/11462; H01L 2224/16245; H01L 2224/81192; H01L 2224/81935

(57) ABSTRACT

A semiconductor device includes: a terminal having a connection surface facing one side in a first direction; a semiconductor element electrically connected to the connection surface; and a sealing resin covering a portion of the terminal and the semiconductor element, wherein the terminal is located on the other side in the first direction with respect to the connection surface and has a first surface recessed into the terminal and a second surface connected to the connection surface and the first surface, wherein the first surface overlaps the connection surface when viewed in the first direction, and wherein the second surface is convex and is in contact with the sealing resin.

### CROSS-REFERENCE TO RELATED APPLICATION

This application is based upon and claims the benefit of priority from Japanese Patent Application No. 2024-091330, filed on Jun. 5, 2024, the entire contents of which are incorporated herein by reference.

### TECHNICAL FIELD

The present disclosure relates to a semiconductor device and a method of manufacturing the semiconductor device.

### BACKGROUND

In the related art, an example of a semiconductor device including a conductive member having a main surface facing in a thickness direction, a semiconductor element conductively bonded to the conductive member, and a sealing resin covering a portion of the conductive member and the semiconductor element is disclosed. The conductive member has a protruding portion including the main surface. The protruding portion is formed by performing half etching on a lead frame. Both sides of the protruding portion in the thickness direction and an end surface of the protruding portion facing in a direction perpendicular to the thickness direction are covered with the sealing resin. This effectively prevents the conductive member from falling off the sealing resin.

In the protruding portion of the conductive member of the semiconductor device disclosed in the related art, a boundary portion between the main surface and the end surface generally has a sharper shape. In a case where the boundary portion has such a shape, a thermal stress caused by heat generated by the semiconductor element is likely to concentrate at the boundary portion. This may cause cracks to occur in the sealing resin that is in contact with the boundary portion.

### BRIEF DESCRIPTION OF DRAWINGS

The accompanying drawings, which are incorporated in and constitute a part of the specification, illustrate embodiments of the present disclosure.

FIG. 1 is a plan view of a semiconductor device according to a first embodiment of the present disclosure.

FIG. 2 is a plan view corresponding to FIG. 1, with a semiconductor element and a sealing resin shown in a transparent manner.

FIG. 3 is a bottom view of the semiconductor device shown in FIG. 1.

FIG. 4 is a right side view of the semiconductor device shown in FIG. 1.

FIG. 5 is a front view of the semiconductor device shown in FIG. 1.

FIG. 6 is a cross-sectional view taken along line VI-VI in FIG. 2.

FIG. 7 is a cross-sectional view taken along line VII-VII in FIG. 2.

FIG. 8 is a cross-sectional view taken along line VIII-VIII in FIG. 2.

FIG. 9 is a partially enlarged cross-sectional view of FIG. 6.

FIG. 10 is a partially enlarged view of FIG. 9.

FIG. 11 is a cross-sectional view for explaining a process of manufacturing the semiconductor device shown in FIG. 1.

FIG. 12 is a cross-sectional view for explaining a process of manufacturing the semiconductor device shown in FIG. 1.

FIG. 13 is a cross-sectional view for explaining a process of manufacturing the semiconductor device shown in FIG. 1.

FIG. 14 is a cross-sectional view for explaining a process of manufacturing the semiconductor device shown in FIG. 1.

FIG. 15 is a partially enlarged cross-sectional view for explaining a process of manufacturing the semiconductor device shown in FIG. 1.

FIG. 16 is a partially enlarged cross-sectional view for explaining a process of manufacturing the semiconductor device shown in FIG. 1.

FIG. 17 is a cross-sectional view for explaining a process of manufacturing the semiconductor device shown in FIG. 1.

FIG. 18 is a cross-sectional view for explaining a process of manufacturing the semiconductor device shown in FIG. 1.

FIG. 19 is a cross-sectional view for explaining a process of manufacturing the semiconductor device shown in FIG. 1.

FIG. 20 is a cross-sectional view for explaining a process of manufacturing the semiconductor device shown in FIG. 1.

FIG. 21 is a cross-sectional view for explaining a process of manufacturing the semiconductor device shown in FIG. 1.

FIG. 22 is a partially enlarged cross-sectional view of a semiconductor device according to a second embodiment of the present disclosure, and corresponds to FIG. 9.

FIG. 23 is a partially enlarged cross-sectional view of a semiconductor device according to a third embodiment of the present disclosure, and corresponds to FIG. 9.

FIG. 24 is a partially enlarged cross-sectional view of a semiconductor device according to a fourth embodiment of the present disclosure, and corresponds to FIG. 9.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Details of the present disclosure will be described with reference to the accompanying drawings.

### First Embodiment

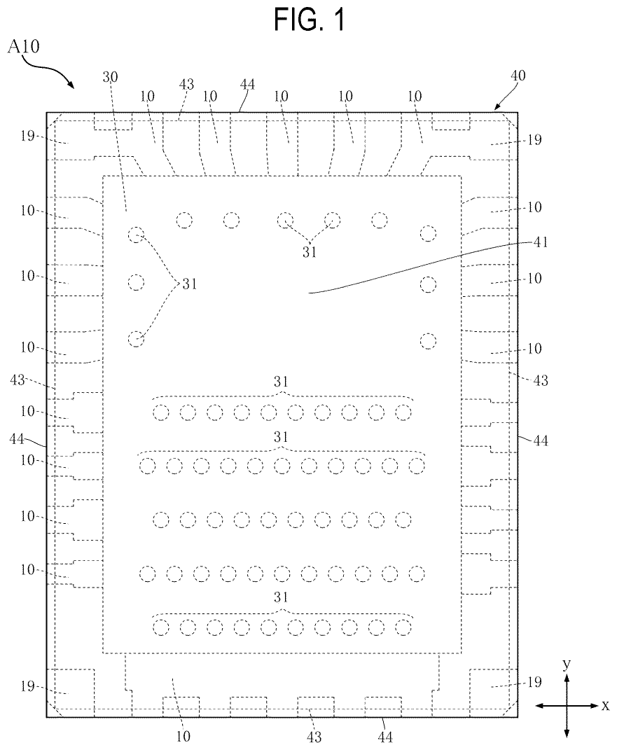

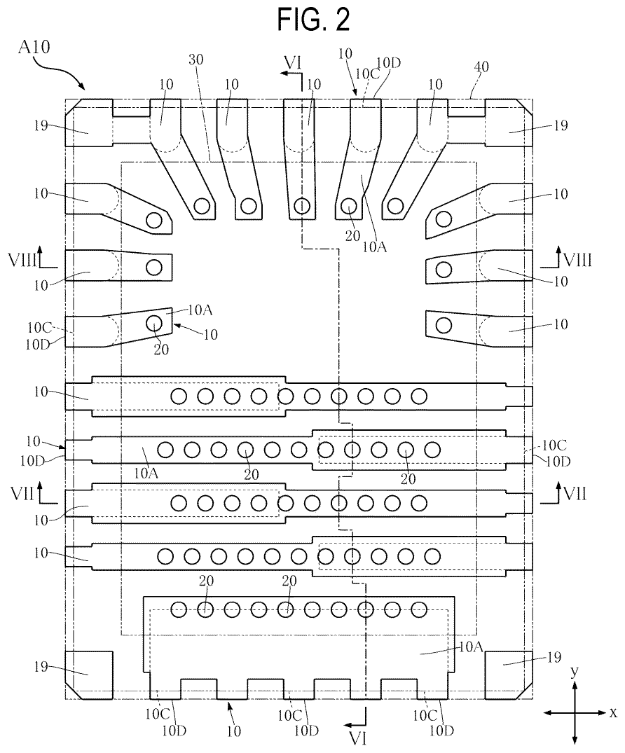

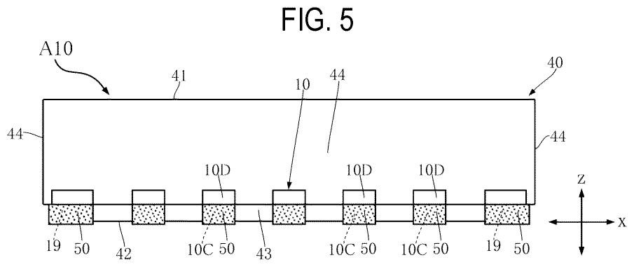

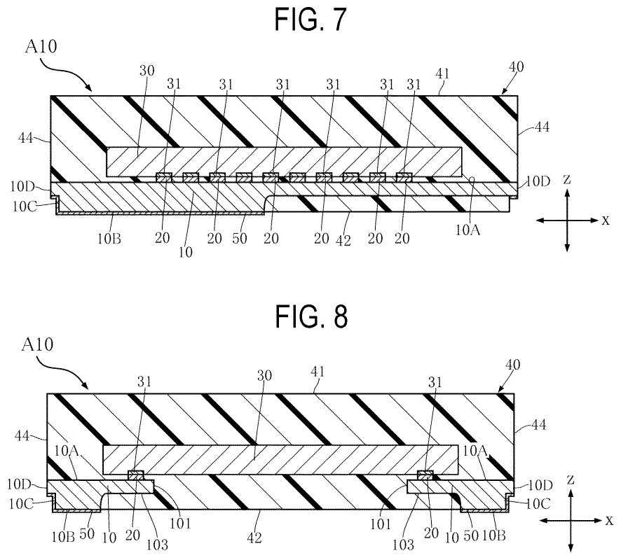

A semiconductor device A10 according to a first embodiment of the present disclosure will be described with reference to FIGS. 1 to 10. The semiconductor device A10 includes a plurality of terminals 10, four dummy terminals 19, a plurality of bonding layers 20, a semiconductor element 30, a sealing resin 40, and a plurality of covering layers 50. The semiconductor device A10 is in a resin package format in which the semiconductor device A10 is surface-mounted on a wiring board. The resin package format is a quad flat non-leaded package (QFN) in which a plurality of leads do not protrude from the sealing resin 40. Here, for ease of understanding, FIG. 2 shows the semiconductor element 30 and the sealing resin 40 in a transparent manner. In FIG. 2, the transparent semiconductor element 30 and sealing resin 40 are each shown with an imaginary line (two-dot chain line). Further, in FIG. 2, line VI-VI is shown with a one-dot chain line.

In the description of the semiconductor device A10, for the sake of convenience, a normal direction of each connection surface 10A of the plurality of terminals 10 to be described later is called a “first direction z.” A direction perpendicular to the first direction z is called a “second direction x.” A direction perpendicular to the first direction z and the second direction x is called a “third direction y.” As shown in FIG. 1, the semiconductor device A10 has a rectangular shape when viewed in the first direction z.

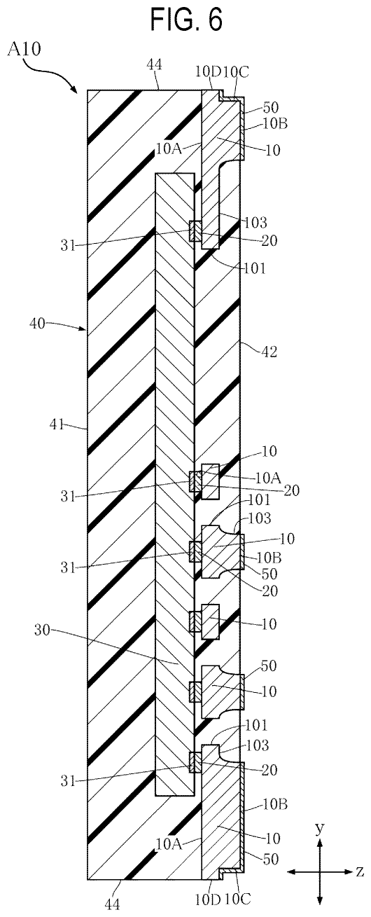

As shown in FIGS. 6 and 8, the sealing resin 40 covers a portion of each of the plurality of terminals 10 and the semiconductor element 30. The scaling resin 40 has an electrical insulation property. An example of a material of the sealing resin 40 may include black epoxy resin.

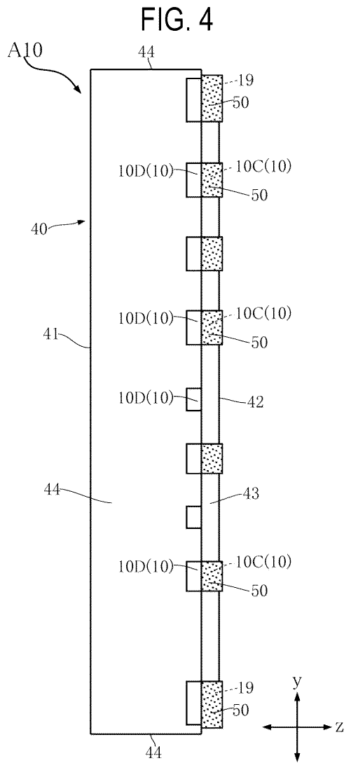

As shown in FIGS. 4 to 8, the sealing resin 40 has a top surface 41, a bottom surface 42, a plurality of first side surfaces 43, and a plurality of second side surfaces 44. The top surface 41 and the bottom surface 42 face opposite sides to each other in the first direction z. The bottom surface 42 faces the opposite side to a side where the semiconductor element 30 is located with respect to the plurality of terminals 10 in the first direction z. Each of the plurality of first side surfaces 43 faces in a direction perpendicular to the first direction z. The plurality of second side surfaces 44 are located between the top surface 41 and the plurality of first side surfaces 43 in the first direction z. Each of the plurality of second side surfaces 44 faces in a direction perpendicular to the first direction z. As viewed in the first direction z, each of the plurality of second side surfaces 44 is located further outward from the semiconductor device A10 than the plurality of first side surfaces 43. Therefore, as viewed in the first direction z, the plurality of first side surfaces 43 are surrounded by the plurality of second side surfaces 44. A dimension of each of the plurality of second side surfaces 44 in the first direction z is larger than a dimension of each of the plurality of first side surfaces 43 in the first direction z.

As shown in FIGS. 6 to 8, the semiconductor element 30 is mounted on the plurality of terminals 10. Each of the plurality of terminals 10 forms a conductive path between the semiconductor element 30 and a wiring board on which the semiconductor device A10 is mounted. The plurality of terminals 10 contain copper (Cu). The plurality of terminals 10 are obtained from a lead frame 81 to be described later.

As shown in FIGS. 6 to 8, each of the plurality of terminals 10 has a connection surface 10A, a mounting surface 10B, a first end surface 10C, and a second end surface 10D. The connection surface 10A faces the same side as the top surface 41 of the sealing resin 40 in the first direction z. The connection surface 10A faces the semiconductor element 30. The connection surface 10A is covered with the sealing resin 40. The mounting surface 10B faces the opposite side to the connection surface 10A in the first direction z. The mounting surface 10B is exposed from the bottom surface 42 of the scaling resin 40. Each of the first end surface 10C and the second end surface 10D faces in a direction perpendicular to the first direction z. The first end surface 10C is exposed from one of the plurality of first side surfaces 43 of the scaling resin 40. The second end surface 10D is located between the connection surface 10A and the first end surface 10C in the first direction z. As viewed in the first direction z, the second end surface 10D is located further outward from the semiconductor device A10 than the first end surface 10C. The second end surface 10D is exposed from one of the plurality of second side surfaces 44 of the scaling resin 40.

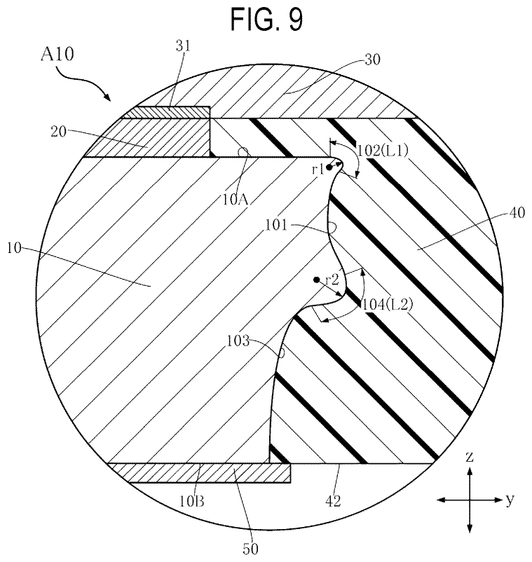

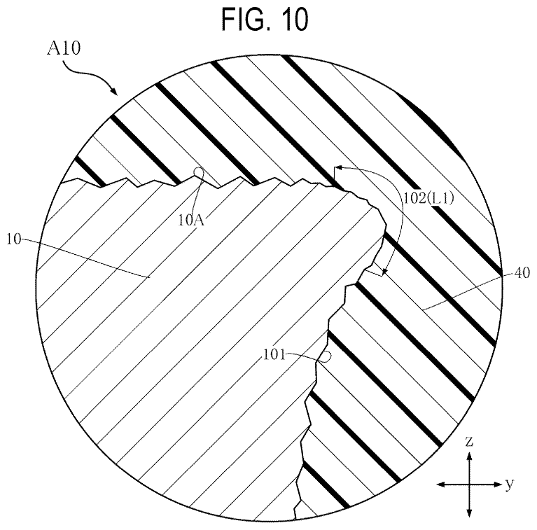

As shown in FIG. 9, each of the plurality of terminals 10 has a first surface 101, a second surface 102, a third surface 103, and a fourth surface 104. The first surface 101 is located on the side where the mounting surface 10B is located in the first direction z with respect to the connection surface 10A. The first surface 101 is recessed into one of the corresponding terminals 10. As viewed in the first direction z, the first surface 101 overlaps the connection surface 10A. The first surface 101 is concave and covered with the scaling resin 40. The second surface 102 is connected to the connection surface 10A and the first surface 101. The second surface 102 is convex and is in contact with the sealing resin 40.

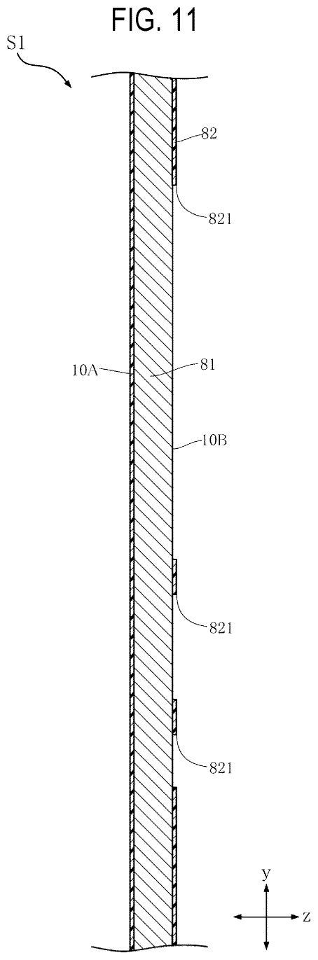

As shown in FIG. 10, a surface roughness of the second surface 102 is smaller than a surface roughness of each of the connection surface 10A and first surface 101.

As shown in FIG. 9, the third surface 103 is located on the opposite side to the connection surface 10A with respect to the first surface 101 in the first direction z. The third surface 103 is recessed into one of the corresponding terminals 10. As viewed in the first direction z, the third surface 103 overlaps the connection surface 10A. The third surface 103 is concave and covered with the sealing resin 40. In each of the plurality of terminals 10, a degree of recession of the third surface 103 is greater than a degree of recession of the first surface 101. The fourth surface 104 is connected to the first surface 101 and the fourth surface 104. The fourth surface 104 is convex and is in contact with the sealing resin 40. As viewed in the first direction z, the second surface 102 overlaps the fourth surface 104.

As shown in FIG. 9, in a cross section of one of the plurality of terminals 10 including the first direction z in an in-plane direction, the second surface 102 and the fourth surface 104 are defined by a first section L1 and a second section L2 respectively. Each of the first section L1 and the second section L2 is curved. A length of the first section L1 is shorter than a length of the second section L2. Further, a radius of curvature r2 of the second section L2 is greater than a radius of curvature r1 of the first section L1.

As shown in FIG. 2, four dummy terminals 19 are disposed at four corners of the semiconductor device A10, respectively. In the semiconductor device A10, the four dummy terminals 19 do not form a conductive path between the semiconductor element 30 and the wiring board on which the semiconductor device A10 is mounted. Each of the four dummy terminals 19 is exposed from the bottom surface 42 of the sealing resin 40, two adjacent first side surfaces 43 among the plurality of first side surfaces 43, and two adjacent second side surfaces 44 among the plurality of second side surfaces 44.

As shown in FIG. 2 and FIGS. 6 to 8, each of the plurality of bonding layers 20 is mounted on one of the connection surfaces 10A of the plurality of terminals 10. Each of the plurality of bonding layers 20 is in contact with the connection surface 10A. Each of the plurality of bonding layers 20 contains nickel (Ni), tin (Sn), and silver (Ag). Alternatively, each of the plurality of bonding layers 20 may contain nickel, tin, and antimony (Sb) or may be a sintered body of metal particles. The metal particles contain, for example, silver.

As shown in FIGS. 6 to 8, the semiconductor element 30 is mounted on the plurality of terminals 10. The semiconductor element 30 is, for example, a large scale integration (LSI). The semiconductor element 30 includes a plurality of electrodes 31.

As shown in FIGS. 6 to 8, each of the plurality of electrodes 31 faces the connection surface 10A of each of the plurality of terminals 10. Each of the plurality of electrodes 31 is conductively bonded to one of the connection surfaces 10A of the plurality of terminals 10 via one of the plurality of bonding layers 20. As a result, the semiconductor element 30 is electrically connected to the connection surface 10A of each of the plurality of terminals 10.

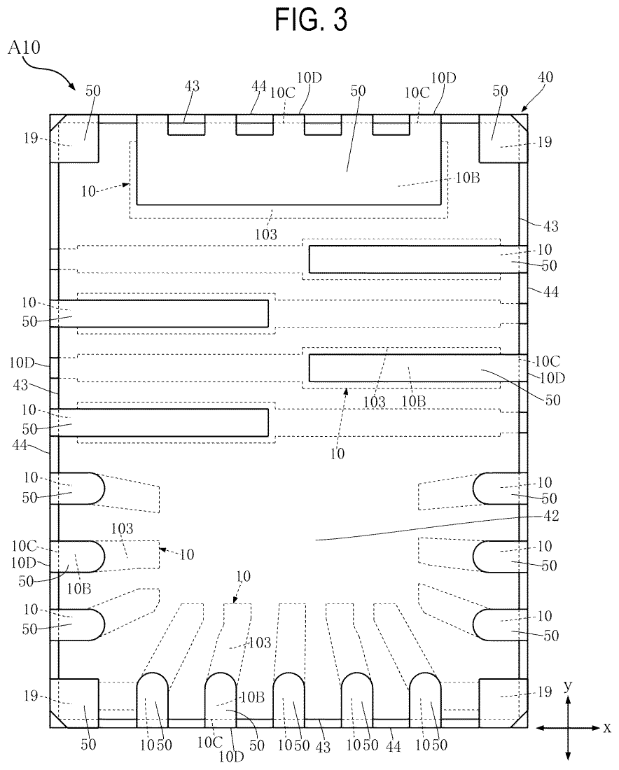

As shown in FIGS. 3 to 8, the plurality of covering layers 50 are exposed to the outside. Each of the plurality of covering layers 50 covers the mounting surface 10B and the first end surface 10C of each of the plurality of terminals 10. The second end surface 10D of each of the plurality of terminals 10 is exposed to the outside from the plurality of covering layers 50. Further, one of the plurality of covering layers 50 covers a region of one of the four dummy terminals 19 that is exposed from the sealing resin 40.

The plurality of covering layers 50 are conductors. The semiconductor device A10 is mounted on the wiring board by conductively bonding the plurality of covering layers 50 to the wiring board via solder. Each of the plurality of covering layers 50 contains a metal element. The metal element is tin.

Further, each of the plurality of covering layers 50 may include a plurality of metal layers. The plurality of metal layers are layered in an order of a nickel layer, a palladium layer (Pd), and a gold (Au) layer from a side closest to a region exposed from the sealing resin 40 of either the plurality of terminals 10 or the plurality of dummy terminals 19. Therefore, in each of the plurality of covering layers 50, the gold layer is exposed to the outside.

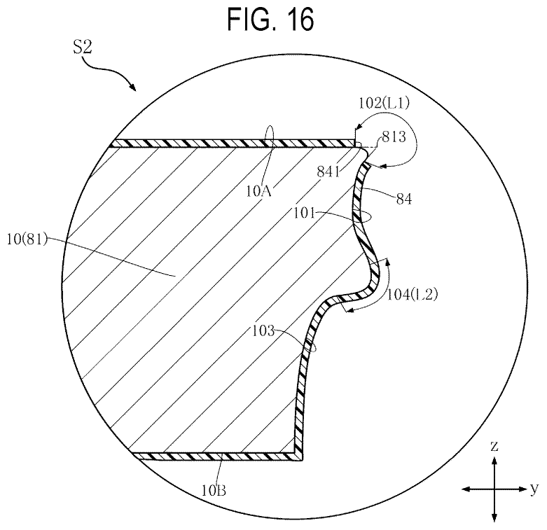

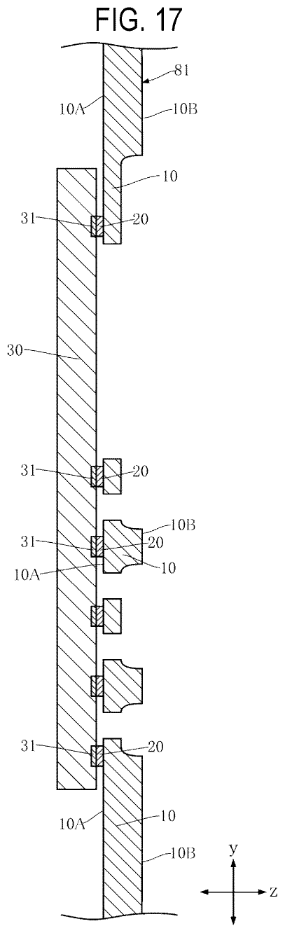

Next, an example of a method of manufacturing the semiconductor device A10 will be described with reference to FIGS. 11 to 21. Here, each of FIGS. 11 to 14 and FIGS. 17 to 21 corresponds to FIG. 6. Each of FIGS. 15 and 16 corresponds to FIG. 9.

First, in the process shown in FIGS. 11 to 16, the plurality of terminals 10 are formed from a lead frame 81. The lead frame 81 is an element that includes the plurality of terminals 10. Therefore, the lead frame 81 includes the connection surface 10A and a mounting surface 10B that face opposite sides from each other in the first direction z. The process of forming the plurality of terminals 10 includes a first step S1 shown in FIGS. 11 to 14 and a second step S2 shown in FIGS. 15 and 16.

In the first step S1, the first surface 101 of each of the plurality of terminals 10 is formed in the lead frame 81. In the first step S1, the first surface 101 is formed by penetrating the lead frame 81 including the connection surface 10A and the mounting surface 10B in the first direction z. First, as shown in FIG. 11, a first resist layer 82 is formed to cover the connection surface 10A and the mounting surface 10B of the lead frame 81. The first resist layer 82 is formed by photolithography patterning. At this time, a plurality of first openings 821 each penetrating in the first direction z are formed in the first resist layer 82. A partial region of the mounting surface 10B is exposed from each of the plurality of first openings 821.

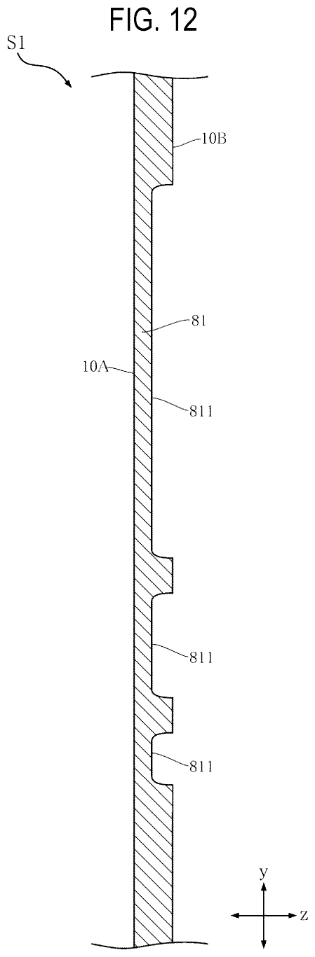

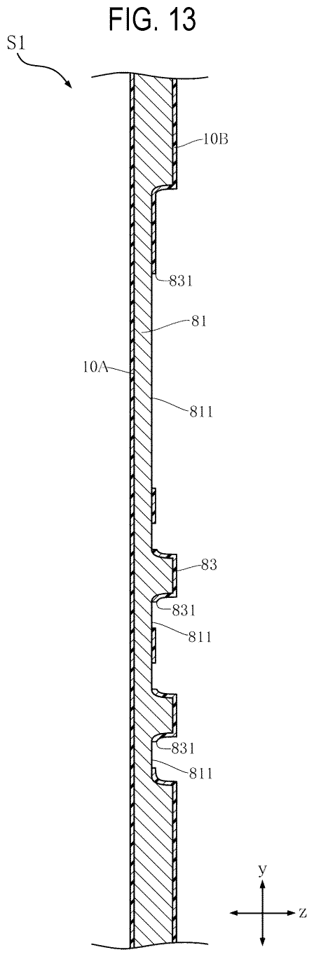

Next, as shown in FIG. 12, a plurality of recessed surfaces 811, which are respectively recessed, are formed in the lead frame 81 from a plurality of regions of the mounting surface 10B that are respectively exposed from each of the plurality of first openings 821 of the first resist layer 82. The plurality of recessed surfaces 811 are formed by etching. After the plurality of recessed surfaces 811 are formed, the first resist layer 82 is removed.

Next, as shown in FIG. 13, a second resist layer 83 is formed to cover the connection surface 10A, the mounting surface 10B, and the plurality of recessed surfaces 811 of the lead frame 81. The second resist layer 83 is formed by photolithography patterning. At this time, a plurality of second openings 831 each penetrating in the first direction z are formed in the second resist layer 83. A partial region of each of the plurality of recessed surfaces 811 is exposed from each of the plurality of second openings 831.

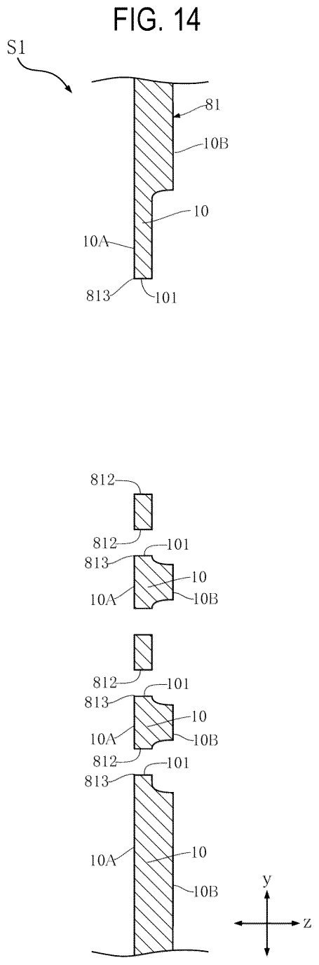

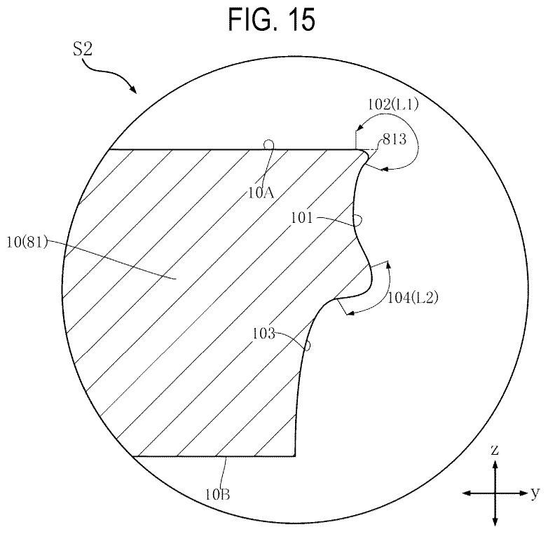

Finally, as shown in FIG. 14, a plurality of penetrating portions 812 penetrating in the first direction z are formed in the lead frame 81 from each region of the plurality of recessed surfaces 811 exposed from each of the plurality of second openings 831 of the second resist layer 83. The plurality of penetrating portions 812 are formed by etching. With the formation of the plurality of penetrating portions 812, the first surface 101 of each of the plurality of terminals 10 and a plurality of boundary portions 813, each of which forms a boundary between the connection surface 10A and one of the first surfaces 101 of the plurality of terminals 10, are formed in the lead frame 81. After the plurality of penetrating portions 812 are formed, the second resist layer 83 is removed. This completes the first step S1.

Next, in the second step S2, the second surface 102 of each of the plurality of terminals 10 is formed in the lead frame 81. As shown in FIG. 15, in the second step S2, the plurality of boundary portions 813 formed in the lead frame 81 are removed by etching, thereby forming the second surface 102 of each of the plurality of terminals 10 in the lead frame 81. From the above, the second step S2 is completed and the plurality of terminals 10 are formed in the lead frame 81.

FIG. 16 shows another manufacturing method in the second step S2. In this manufacturing method, before forming the second surface 102 of each of the plurality of terminals 10, a third resist layer 84 covering the lead frame 81 is formed. The third resist layer 84 is formed by photolithography patterning. At this time, a plurality of third openings 841 through which the plurality of boundary portions 813 formed in the lead frame 81 are respectively exposed are formed in the third resist layer 84. Next, the plurality of boundary portions 813 respectively exposed from the plurality of third openings 841 are removed by etching. Finally, the third resist layer 84 is removed. As a result, the second surface 102 of each of the plurality of terminals 10 is formed on the lead frame 81.

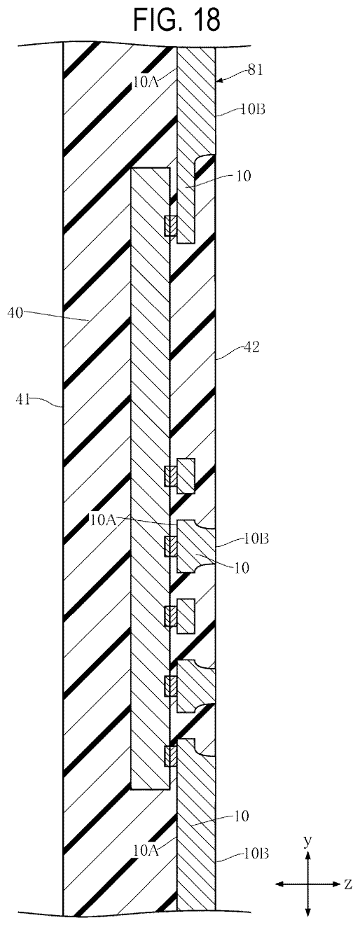

Next, as shown in FIG. 17, the semiconductor element 30 electrically connected to each connection surface 10A of the plurality of terminals 10 is disposed. First, the plurality of bonding layers 20 are formed on each connection surface 10A of the plurality of terminals 10. The plurality of bonding layers 20 are formed by performing photolithography patterning on each connection surface 10A of the plurality of terminals 10 and then depositing a plurality of metal layers by electrolytic plating using the lead frame 81 as a conductive path. Then, each of the plurality of electrodes 31 of the semiconductor element 30 is conductively bonded to one of the plurality of terminals 10. The conductive bonding of the semiconductor element 30 is performed by flip-chip bonding. The conductive bonding of the semiconductor element 30 is achieved by temporarily attaching the plurality of electrodes 31 to the plurality of bonding layers 20 respectively and then melting and solidifying the plurality of bonding layers 20 by reflow.

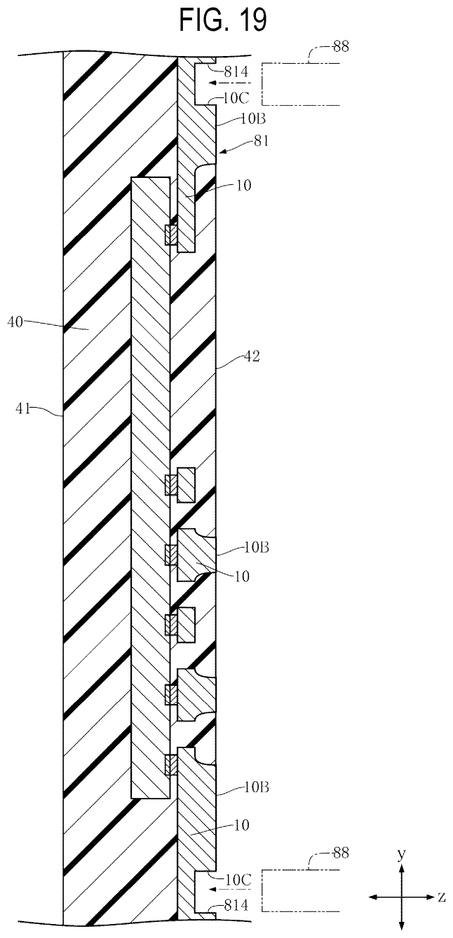

Next, as shown in FIG. 18, the sealing resin 40 is formed to cover a portion of each of the plurality of terminals 10 and the semiconductor element 30. Through this step, the top surface 41 and the bottom surface 42 are formed in the scaling resin 40, and the mounting surface 10B of each of the plurality of terminals 10 is exposed from the bottom surface 42.

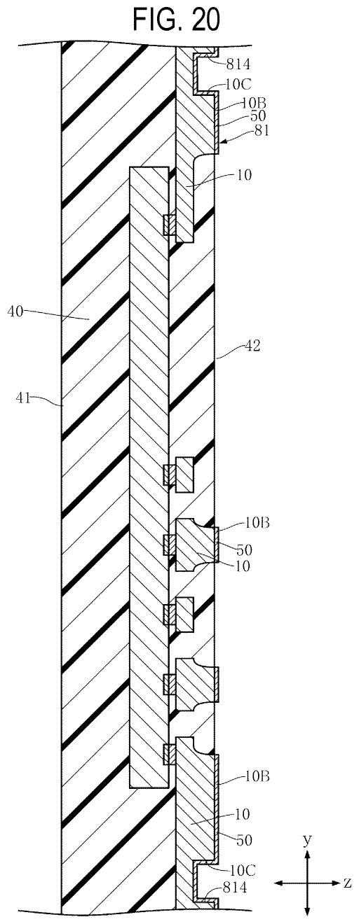

Next, as shown in FIG. 19, a plurality of grooves 814 are formed to be recessed from the mounting surface 10B of each of the plurality of terminals 10 and the bottom surface 42 of the sealing resin 40. The plurality of grooves 814 are formed by removing a portion of the bottom surface 42 by using a first blade 88. The plurality of grooves 814 are formed in a lattice shape along the second direction x and the third direction y. This step forms the plurality of first side surfaces 43 in the sealing resin 40 and forms the first end surface 10C exposed from one of the plurality of first side surfaces 43 in each of the plurality of terminals 10.

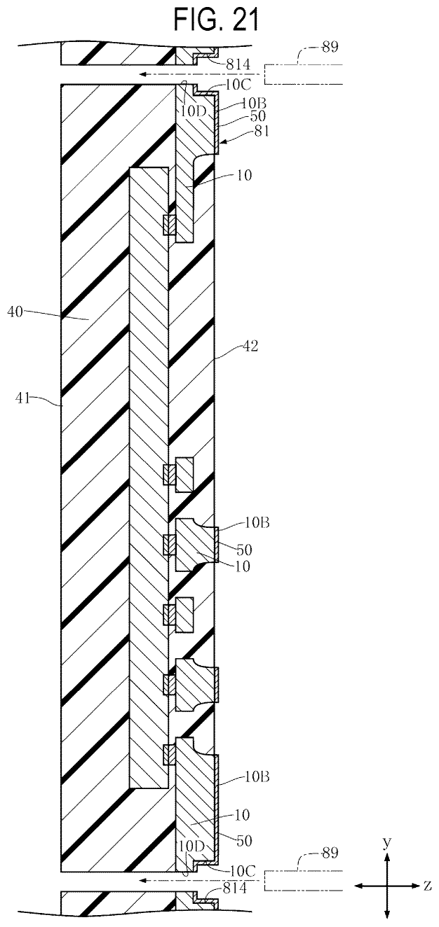

Next, as shown in FIG. 20, the plurality of covering layers 50 are formed to respectively cover the mounting surface 10B and the first end surface 10C of each of the plurality of terminals 10. The plurality of covering layers 50 are formed by electrolytic plating using the lead frame 81 as a conductive path. Alternatively, the plurality of covering layers 50 can be formed by electroless plating.

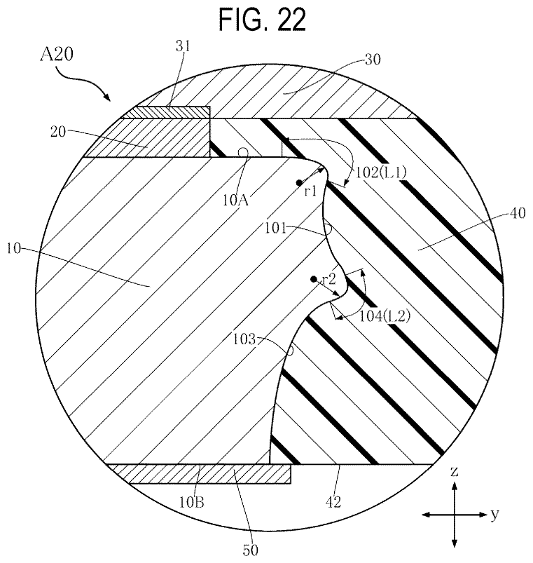

Finally, as shown in FIG. 21, the lead frame 81 and the sealing resin 40 are cut by using a second blade 89. In this step, the lead frame 81 and the sealing resin 40 are cut by inserting the second blade 89 into the plurality of grooves 814 formed in the sealing resin 40. A thickness of the second blade 89 is set to be smaller than a thickness of the first blade 88. This step forms the plurality of second side surfaces 44 formed in the scaling resin 40 and forms the second end surface 10D exposed from one of the plurality of second side surfaces 44 in each of the plurality of terminals 10. Through the above steps, the semiconductor device A10 is obtained.

Next, operations and effects of the semiconductor device A10 will be described.

The semiconductor device A10 includes the terminals 10, the semiconductor element 30, and the sealing resin 40. Each terminal 10 has the connection surface 10A, the first surface 101, and the second surface 102. As viewed in the first direction z, the first surface 101 overlaps the connection surface 10A. The second surface 102 is convex and is in contact with the sealing resin 40. By adopting this configuration, a shape of the second surface 102 becomes more rounded than before. As a result, even in a case where a thermal stress due to heat generated from the semiconductor element 30 occurs in the second surface 102, the thermal stress transmitted from the second surface 102 to the sealing resin 40 is reduced. Therefore, according to this configuration, it is possible to suppress occurrence of cracks in the sealing resin 40 in the semiconductor device A10.

The first surface 101 of each terminal 10 is concave and is covered with the sealing resin 40. By adopting this configuration, the sealing resin 40 exhibits an anchor effect on the terminal 10. This makes it possible to effectively prevent the terminal 10 from falling off the sealing resin 40.

Each terminal 10 has the third surface 103. As viewed in the first direction z, the third surface 103 overlaps the connection surface 10A. The third surface 103 is concave and is in contact with the sealing resin 40. In the terminal 10, a degree of recession of the third surface 103 is greater than a degree of recession of the first surface 101. By adopting this configuration, an area of the sealing resin 40 in contact with each of the connection surface 10A and the third surface 103 in the terminal 10 is further increased. This makes it possible to more effectively prevent the terminal 10 from falling off the sealing resin 40.

The surface roughness of the second surface 102 is smaller than the surface roughness of each of the connection surface 10A and the first surface 101. By adopting this configuration, it is possible to effectively reduce the thermal stress transmitted from the second surface 102 to the scaling resin 40.

Each terminal 10 has the fourth surface 104. The fourth surface 104 is convex and is in contact with the sealing resin 40. In a cross section of the terminal 10 including the first direction z in an in-plane direction, the second surface 102 and the fourth surface 104 are defined by the first section L1 and the second section L2, respectively. Each of the first section L1 and the second section L2 is curved. The length of the first section L1 is shorter than the length of the second section L2. By adopting this configuration, it is possible to prevent excessive reduction in an area of the connection surface 10A while reducing the thermal stress transmitted from the second surface 102 to the sealing resin 40.

The radius of curvature r2 of the second section L2 is larger than the radius of curvature r1 of the first section L1. By adopting this configuration, it is possible to make distribution of the thermal stress transmitted from the terminal 10 to the scaling resin 40 more uniform.

The semiconductor device A10 further includes the covering layers 50 each covering the mounting surface 10B of the terminal 10. Each covering layer 50 contains a metal element. By adopting this configuration, when the semiconductor device A10 is mounted on a wiring board, wettability of solder to the terminal 10 is improved. This improves a mounting strength of the semiconductor device A10 to the wiring board.

The semiconductor device A10 further includes the four dummy terminals 19 disposed at the four corners of the semiconductor device A10 when viewed in the first direction z. The four dummy terminals 19 do not form a conductive path between the semiconductor element 30 and the wiring board on which the semiconductor device A10 is mounted. By adopting this configuration, it is possible to concentrate the thermal stress caused by the heat generated from the semiconductor device A10 on the four dummy terminals 19. This makes it possible to suppress the occurrence of cracks in the solder bonding the wiring board and the terminal 10.

### Second Embodiment

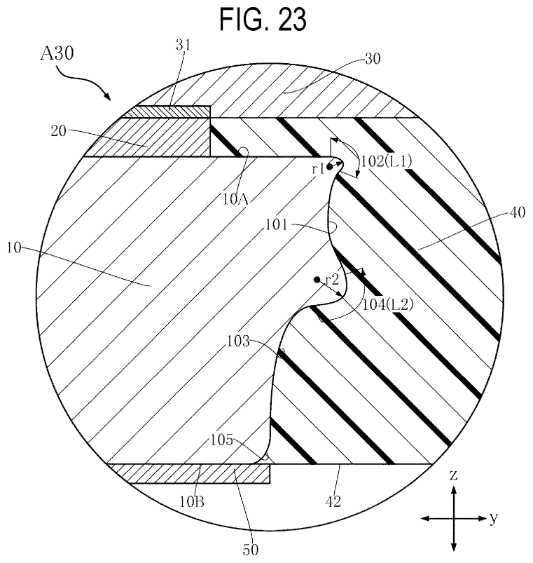

A semiconductor device A20 according to a second embodiment of the present disclosure will be described with reference to FIG. 22. In this figure, elements that are the same as or similar to those of the above-described semiconductor device A10 are denoted by the same reference numerals, and a duplicate explanation thereof will be omitted. Here, FIG. 22 corresponds to FIG. 9 showing the semiconductor device A10.

In the semiconductor device A20, a configuration of the plurality of terminals 10 is different from that of the semiconductor device A10.

As shown in FIG. 22, in each of the plurality of terminals 10, the second surface 102 overlaps the third surface 103 when viewed in the first direction z.

Next, operations and effects of the semiconductor device A20 will be described.

The semiconductor device A20 includes the terminals 10, the semiconductor element 30, and the sealing resin 40. Each terminal 10 has the connection surface 10A, the first surface 101, and the second surface 102. As viewed in the first direction z, the first surface 101 overlaps the connection surface 10A. The second surface 102 is convex and is in contact with the sealing resin 40. Therefore, according to this configuration, it is possible to suppress the occurrence of cracks in the sealing resin 40 in the semiconductor device A20 as well. Further, the semiconductor device A20 has a configuration common to the semiconductor device A10, and thus exhibits the same operations and effects as those of the semiconductor device A10.

In the semiconductor device A20, the second surface 102 of the terminal 10 overlaps the third surface 103 of the terminal 10 when viewed in the first direction z. By adopting this configuration, in FIG. 22, the first section L1 defining the second surface 102 becomes longer, and the radius of curvature r1 of the first section L1 becomes larger. As a result, the thermal stress transmitted from the second surface 102 to the sealing resin 40 due to the heat generated from the semiconductor element 30 is more effectively reduced.

### Third Embodiment

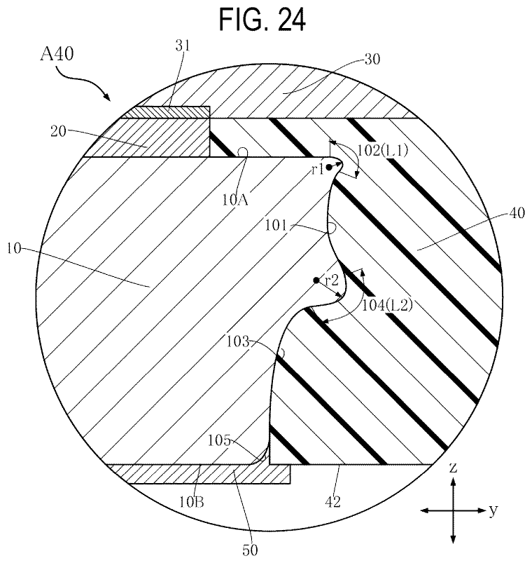

A semiconductor device A30 according to a third embodiment of the present disclosure will be described with reference to FIG. 23. In this figure, elements that are the same as or similar to those of the above-described semiconductor device A10 are denoted by the same reference numerals, and a duplicate explanation thereof will be omitted. Here, FIG. 23 corresponds to FIG. 9 showing the semiconductor device A10.

In the semiconductor device A30, a configuration of the plurality of terminals 10 is different from that of the semiconductor device A10.

As shown in FIG. 23, each of the plurality of terminals 10 has a fifth surface 105. The fifth surface 105 is connected to the third surface 103 and the mounting surface 10B. The fifth surface 105 is convex. In the semiconductor device A30, the fifth surface 105 is in contact with the sealing resin 40.

Next, operations and effects of the semiconductor device A30 will be described.

The semiconductor device A30 includes the terminals 10, the semiconductor element 30, and the sealing resin 40. Each terminal 10 has the connection surface 10A, the first surface 101, and the second surface 102. As viewed in the first direction z, the first surface 101 overlaps the connection surface 10A. The second surface 102 is convex and is in contact with the sealing resin 40. Therefore, according to this configuration, it is possible to suppress the occurrence of cracks in the sealing resin 40 in the semiconductor device A30 as well. Further, the semiconductor device A30 has a configuration common to the semiconductor device A10, and thus exhibits the same operations and effects as those of the semiconductor device A10.

In the semiconductor device A30, the terminal 10 has the fifth surface 105 connected to the third surface 103 and the mounting surface 10B. The fifth surface 105 is convex. Here, in the manufacture of the semiconductor device A10, metal burrs may be formed at the boundary between the third surface 103 and the mounting surface 10B in the step shown in FIG. 12. When the semiconductor device A10 where the metal burrs are formed is mounted on a wiring board, there is a concern that a mounting state of the semiconductor device A10 on the wiring board may deteriorate. Therefore, by adopting this configuration, the metal burrs are removed from the semiconductor device A30. This allows a mounting state of the semiconductor device A30 on the wiring board to be improved.

### Fourth Embodiment

A semiconductor device A40 according to a fourth embodiment of the present disclosure will be described with reference to FIG. 24. In this figure, elements that are the same as or similar to those of the above-described semiconductor device A10 are denoted by the same reference numerals, and a duplicate explanation thereof will be omitted. Here, FIG. 24 corresponds to FIG. 9 showing the semiconductor device A10.

In the semiconductor device A40, a configuration of the plurality of terminals 10 is different from that of the semiconductor device A30.

As shown in FIG. 24, the fifth surface 105 of each of the plurality of terminals 10 is in contact with one of the plurality of covering layers 50.

Next, operations and effects of the semiconductor device A40 will be described.

The semiconductor device A40 includes the terminals 10, the semiconductor element 30, and the sealing resin 40. Each terminal 10 has the connection surface 10A, the first surface 101, and the second surface 102. As viewed in the first direction z, the first surface 101 overlaps the connection surface 10A. The second surface 102 is convex and is in contact with the sealing resin 40. Therefore, according to this configuration, it is possible to suppress the occurrence of cracks in the sealing resin 40 in the semiconductor device A40 as well. Further, the semiconductor device A40 has a configuration common to the semiconductor device A10, and thus exhibits the same operations and effects as those of the semiconductor device A10.

In the semiconductor device A40, the fifth surface 105 of the terminal 10 is in contact with the covering layer 50. By adopting this configuration, when the semiconductor device A40 is mounted on a wiring board, the covering layer 50 exhibits an anchor effect on the fifth surface 105. This makes it possible to improve a mounting strength of the semiconductor device A40 while improving the mounting state of the semiconductor device A40 on the wiring board.

The present disclosure is not limited to the above-described embodiments. The specific configuration of each part of the present disclosure can be freely designed in various ways.

The present disclosure includes embodiments described in the supplementary notes set forth below.

### [Supplementary Note 1]

A semiconductor device (A10) including:
a terminal (10) having a connection surface (10A) facing one side in a first direction (z);
a semiconductor element (30) electrically connected to the connection surface; and
a sealing resin (40) covering a portion of the terminal and the semiconductor element,
wherein the terminal is located on the other side in the first direction with respect to the connection surface and has a first surface (101) recessed into the terminal and a second surface (102) connected to the connection surface and the first surface,
wherein the first surface overlaps the connection surface when viewed in the first direction, and
wherein the second surface is convex and is in contact with the sealing resin.

### [Supplementary Note 2]

The semiconductor device (A10) of Supplementary Note 1, wherein the first surface (101) is concave.

### [Supplementary Note 3]

The semiconductor device (A10) of Supplementary Note 2, wherein the first surface (101) is covered with the sealing resin (40).

### [Supplementary Note 4]

The semiconductor device (A10) of Supplementary Note 3, wherein the terminal (10) is located on an opposite side to the connection surface (10A) with respect to the first surface (101) and has a third surface (103) recessed into the terminal, and
wherein the third surface overlaps the connection surface when viewed in the first direction (z).

### [Supplementary Note 5]

The semiconductor device (A10) of Supplementary Note 4, wherein the third surface (103) is concave and is covered with the sealing resin (40).

### [Supplementary Note 6]

The semiconductor device (A10) of Supplementary Note 5, wherein, in the terminal (10), a degree of recession of the third surface (103) is greater than a degree of recession of the first surface (101).

### [Supplementary Note 7]

The semiconductor device (A10) of Supplementary Note 6, wherein the terminal (10) has a fourth surface (104) connected to the first surface (101) and the third surface (103), and wherein the fourth surface is convex and is in contact with the sealing resin (40).

### [Supplementary Note 8]

The semiconductor device (A10) of Supplementary Note 7, wherein, in a cross section of the terminal (10) including the first direction (z) in an in-plane direction, the second surface (102) and the fourth surface (104) are defined by a first section (L1) and a second section (L2), respectively,
wherein each of the first section and the second section is curved, and
wherein a length of the first section is shorter than a length of the second section.

### [Supplementary Note 9]

The semiconductor device (A10) of Supplementary Note 8, wherein a radius of curvature (r1) of the first section (L1) is smaller than a radius of curvature (r2) of the second section (L2).

### [Supplementary Note 10]

The semiconductor device (A20) of Supplementary Note 7, wherein the second surface (102) overlaps the third surface (103) when viewed in the first direction (z).

### [Supplementary Note 11]

The semiconductor device (A10) of any one of Supplementary Notes 7 to 10, wherein the terminal (10) has a mounting surface (10B) facing an opposite side to the connection surface (10A) in the first direction (z), and
wherein the mounting surface is exposed from the sealing resin (40).

### [Supplementary Note 12]

The semiconductor device (A10) of Supplementary Note 11, wherein the semiconductor element (30) includes an electrode (31) facing the connection surface (10A), and
wherein the electrode is conductively bonded to the connection surface.

### [Supplementary Note 13]

The semiconductor device (A10) of Supplementary Note 11, further including a covering layer (50) covering the mounting surface (10B),
wherein the covering layer contains a metal element.

### [Supplementary Note 14]

The semiconductor device (A30, A40) of Supplementary Note 13, wherein the terminal (10) has a fifth surface (105) connected to the third surface (103) and the mounting surface (10B), and
wherein the fifth surface is convex.

### [Supplementary Note 15]

The semiconductor device (A40) of Supplementary Note 14, wherein the fifth surface (105) is in contact with the covering layer (50).

### [Supplementary Note 16]

The semiconductor device (A10) of Supplementary Note 13, wherein the terminal (10) has a first end surface (10C) facing in a direction perpendicular to the first direction (z), and
wherein the first end surface is covered with the covering layer (50).

### [Supplementary Note 17]

A method of manufacturing a semiconductor device (A10), including:
forming a terminal (10) having a connection surface (10A) facing one side in a first direction (z);
disposing a semiconductor element (30) electrically connected to the connection surface; and
forming a sealing resin (40) covering a portion of the terminal and the semiconductor element,
wherein the forming the terminal includes a first process (S1) of forming a first surface (101) that is located on the other side in the first direction with respect to the connection surface and is recessed into the terminal, and a second process (S2) of forming a second surface (102) that is connected to the connection surface and the first surface,
wherein the first process includes forming the first surface by penetrating a lead frame (81) including the connection surface in the first direction, and
wherein the second process includes forming the second surface by removing, through etching, a portion of the lead frame that forms a boundary between the connection surface and the first surface.

### [Supplementary Note 18]

The method of Supplementary Note 17, wherein the lead frame (81) includes a mounting surface (10B) facing an opposite side to the connection surface (10A) in the first direction (z),
wherein the first process (S1) includes:
   forming a first resist layer (82) that has a first opening (821) exposing the mounting surface and covers the lead frame;
   forming a recessed surface (811), which is recessed from the mounting surface exposed from the first opening, in the lead frame;
   forming a second resist layer (83) that has a second opening (831) exposing the recessed surface and covers the lead frame; and
   forming a penetrating portion (812), which penetrates in the first direction from the recessed surface exposed from the second opening, in the lead frame,
wherein the first surface (101) defines the penetrating portion, and
wherein each of the recessed surface and the penetrating portion is formed by etching.

### [Supplementary Note 19]

The method of Supplementary Note 18, wherein the second process (S2) includes forming a third resist layer (84) covering the lead frame (81) before forming the second surface (102), and
wherein the third resist layer has a third opening (841) exposing a portion of the lead frame that forms a boundary between the connection surface (10A) and the first surface (101).

### [Supplementary Note 20]

The semiconductor device (A10) of Supplementary Note 5, wherein a surface roughness of the second surface (102) is smaller than a surface roughness of each of the connection surface (10A) and the first surface (101).

### [Supplementary Note 21]

The semiconductor device (A10) of Supplementary Note 14, wherein the metal element includes either tin or gold.

### [Supplementary Note 22]

The semiconductor device (A30) of Supplementary Note 15, wherein the fifth surface (105) is in contact with the sealing resin (40).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a terminal having a connection surface facing one side in a first direction;
a semiconductor element electrically connected to the connection surface; and
a sealing resin covering a portion of the terminal and the semiconductor element,
wherein the terminal is located on the other side in the first direction with respect to the connection surface and has a first surface recessed into the terminal and a second surface connected to the connection surface and the first surface,
wherein the first surface overlaps the connection surface when viewed in the first direction, and
wherein the second surface is convex and is in contact with the sealing resin.

2. The semiconductor device of claim 1, wherein the first surface is concave.

3. The semiconductor device of claim 2, wherein the first surface is covered with the sealing resin.

4. The semiconductor device of claim 3, wherein the terminal is located on an opposite side to the connection surface with respect to the first surface and has a third surface recessed into the terminal, and
wherein the third surface overlaps the connection surface when viewed in the first direction.

5. The semiconductor device of claim 4, wherein the third surface is concave and is covered with the sealing resin.

6. The semiconductor device of claim 5, wherein, in the terminal, a degree of recession of the third surface is greater than a degree of recession of the first surface.

7. The semiconductor device of claim 6, wherein the terminal has a fourth surface connected to the first surface and the third surface, and
wherein the fourth surface is convex and is in contact with the sealing resin.

8. The semiconductor device of claim 7, wherein, in a cross section of the terminal including the first direction in an in-plane direction, the second surface and the fourth surface are defined by a first section and a second section, respectively,
wherein each of the first section and the second section is curved, and
wherein a length of the first section is shorter than a length of the second section.

9. The semiconductor device of claim 8, wherein a radius of curvature of the first section is smaller than a radius of curvature of the second section.

10. The semiconductor device of claim 7, wherein the second surface overlaps the third surface when viewed in the first direction.

11. The semiconductor device of claim 7, wherein the terminal has a mounting surface facing an opposite side to the connection surface in the first direction, and
wherein the mounting surface is exposed from the sealing resin.

12. The semiconductor device of claim 11, wherein the semiconductor element includes an electrode facing the connection surface, and
wherein the electrode is conductively bonded to the connection surface.

13. The semiconductor device of claim 11, further comprising a covering layer covering the mounting surface,
wherein the covering layer contains a metal element.

14. The semiconductor device of claim 13, wherein the terminal has a fifth surface connected to the third surface and the mounting surface, and
wherein the fifth surface is convex.

15. The semiconductor device of claim 14, wherein the fifth surface is in contact with the covering layer.

16. The semiconductor device of claim 13, wherein the terminal has a first end surface facing in a direction perpendicular to the first direction, and
wherein the first end surface is covered with the covering layer.

17. A method of manufacturing a semiconductor device, comprising:
forming a terminal having a connection surface facing one side in a first direction;
disposing a semiconductor element electrically connected to the connection surface; and
forming a sealing resin covering a portion of the terminal and the semiconductor element,
wherein the forming the terminal includes a first process of forming a first surface that is located on the other side in the first direction with respect to the connection surface and is recessed into the terminal, and a second process of forming a second surface that is connected to the connection surface and the first surface,
wherein the first process includes forming the first surface by penetrating a lead frame including the connection surface in the first direction, and
wherein the second process includes forming the second surface by removing, through etching, a portion of the lead frame that forms a boundary between the connection surface and the first surface.

18. The method of claim 17, wherein the lead frame includes a mounting surface facing an opposite side to the connection surface in the first direction,
wherein the first process includes:
forming a first resist layer that has a first opening exposing the mounting surface and covers the lead frame;
forming a recessed surface, which is recessed from the mounting surface exposed from the first opening, in the lead frame;
forming a second resist layer that has a second opening exposing the recessed surface and covers the lead frame; and
forming a penetrating portion, which penetrates in the first direction from the recessed surface exposed from the second opening, in the lead frame,
wherein the first surface defines the penetrating portion, and
wherein each of the recessed surface and the penetrating portion is formed by etching.

19. The method of claim 18, wherein the second process includes forming a third resist layer covering the lead frame before forming the second surface, and
wherein the third resist layer has a third opening exposing the portion of the lead frame that forms the boundary between the connection surface and the first surface.
